(19) United States
(12) Patent Application Publication
(10) Pub. No.: US 2006/0091464 A1
(43) Pub. Date: May 4, 2006

(54) Electrostatic protection circuit

(76) Inventor: Takayuki Hiraoka, Kawasaki-Shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 11/220,950

(22) Filed: Sep. 6, 2005

(30) Foreign Application Priority Data
Sep. 7, 2004 (JP) 2004-260130

(51) Int. Cl. H01L 23/62

(52) U.S. Cl. 257/355

(57) ABSTRACT

An electrostatic protection circuit includes a thyristor that discharges an excess charge generated between a first power supply terminal and a second power supply terminal having a lower voltage than the first power supply terminal, a trigger device that supplies a current turning on the thyristor, and an electrostatic discharge element placed between the first power supply terminal and the second power supply terminal in parallel with thyristor and having a higher current supply capability than the trigger device at the same inter-power-terminal voltage, the electrostatic element changing to an on state in a time shorter than a turn-on time of the thyristor connected to the trigger device and at a voltage lower than a turn-on voltage of the thyristor.

### CROSS REFERENCE TO RELATED APPLICATIONS

This application is based upon and claims the benefit of priority from the prior Japanese Patent Application No. 2004-260130, filed on Sep. 7, 2004, the entire contents of which are incorporated herein by reference.

### BACKGROUND

1. Field of the Invention

The present invention relates to an electrostatic protection circuit that prevents a current such as an electrostatic surge from flowing into a semiconductor device.

2. Related Art

An electrostatic protection circuit and electrostatic protection elements are integrated together inside an LSI in order to protect an internal circuit from electrostatic discharge damage caused by an external over-current. A thyristor used as an electrostatic protection element, can hold a high discharge capability after being turned on. The thyristor is thus suitable as an electrostatic protection circuit.

In general, a thyristor protection circuit has, for example, a pnp-type bipolar junction transistor (referred to as a BIT (Bipolar Junction Transistor) below) interposed in the junction line between a power supply pad and a ground pad and having an emitter connected to the power supply pad, an npn-type BJT having a collector connected to a base of the pnp-type BJT, an emitter connected to the ground pad, and a base connected to the collector of the pnp-type BJT, and a resistor interposed between the junction point between the collector of the pnp-type BJT and the base of the npn-type BJT and the junction point between the emitter of the npn-type BJT and the ground pad. Moreover, a trigger element is connected to the junction point between base of the pnp-type BJT and the collector of the npn-type BJT and in parallel with the thyristor.

A problem with the above general thyristor protection circuit is that a latch state may occur during a normal operation depending on the configuration of the circuit. Thus, two measures have been taken in order to improve the latch-up resistance of the thyristor protection circuit. The former measure is a circuit configuration according to a first conventional example which is described in U.S. Pat. No. 6,433,368 and Japanese Patent No. 2938571. The latter measure is a second conventional example in which the values of base resistances offered by two BJTs constituting the thyristor are adjusted.

As described in U.S. Pat. No. 6,433,368, in the electrostatic protection circuit according to the first conventional example, a diode is connected in series between a thyristor and a first power supply terminal in a general thyristor protection circuit. One of the techniques relating to the first conventional example is the circuit configuration described in Japanese Patent No. 2938571. The electrostatic protection circuit described in Japanese Patent No. 2938571 includes a Zener diode connected between the first power supply terminal and the emitter of the pnp-type BJT.

In the second conventional example, that is, the latter measure for improving the latch-up resistance of the thyristor protection circuit, the base resistances of the npn-type BJT and pnp-type BJT in the general thyristor protection circuit are reduced to several Ω to several tens of Ω and are each connected between the emitter and base of the corresponding BJT. The second conventional example is the techniques described in U.S. Pat. No. 5,747,834 and U.S. Pat. No. 6,031,405. U.S. Pat. No. 5,747,834 uses a normal static resistor and U.S. Pat. No. 6,031,405 uses a transistor as a resistance element. Besides the above patent publications, this technique is described in the document “High Holding Current SCRs (HHI-SCR) for ESD Protection and Latch-up Immune IC Operation”, 2002, EOS/ESD, Markus P. J. Mergens et al.

The configuration of the first conventional example is known as a technique for increasing the hold voltage Vh of an ESD protection circuit including a thyristor. Provided that the hold voltage Vh is set at a value sufficiently higher than a standby voltage, even when the thyristor is turned on, it finally returns to the original off state. A problem with this configuration is that the series insertion of the diode degrades a discharge capability owing to the parasitic resistance of the diode and the forward voltage of the forward-biased diode (see FIG. 9, described below).

For the configuration of the second conventional example, the base resistance is designed to have a small value so that carriers are unlikely to be held in a p-well region of the thyristor constructed on silicon (see FIG. 8, described below). This increases the quantity of current required to turn on the thyristor, thus preventing inadvertent turn-on resulting from power supply noise or the like. Further, even if a hold voltage Vh is raised to turn on the thyristor, a current flowing through the circuit returns to the level of a leakage current that may be generated during a normal operation after an electrostatic surge is discharged. In other words, latch-up does not occur.

A problem with the circuit according to the second conventional example is that carriers are unlikely to be held in the well region, so that the turn-on time of the thyristor is increased. This is disadvantageous to electrostatic protection of a thin oxide film that is not resistant to transitional voltage stress.

In short, in the first and second conventional examples, that is, the conventional measures, there is a trade-off between improvement of resistance to latch-up and degradation of discharge capability of the electrostatic protection circuit or an increase in turn-on time.

With reference to the characteristic diagrams in FIGS. 9 and 10, description will be given of the current-voltage characteristic of the conventional electrostatic protection circuit. FIG. 9 shows a difference in I-V characteristic between a common thyristor protection circuit and the electrostatic protection circuit according to the first conventional example. A solid line 41 shows the I-V characteristic of the common thyristor protection circuit. In contrast, a dashed line 42 shows the I-V characteristic of the electrostatic protection circuit according to the first conventional example. The voltage level shown by a dashed line 43 is a standby voltage equal to a power supply voltage Vdd supplied to the power supply terminal. A solid circle 44 shows the hold voltage of the electrostatic protection circuit, which uses a thyristor. In the first conventional example, in which the diode is interposed between the power supply terminal and the emitter of the pnp-type BJT, the hold voltage can be increased above the standby voltage as shown by a dashed circle 45 on the line showing the characteristic shown by the dashed line 42. This is for preventing latch-up. FIG. 10 shows a variation in I-V characteristic depending on the resistance value of the resistance between the base and emitter of the npn-type BJT in the common thyristor protection circuit. A solid line 51 shows the I-V characteristic obtained if the base resistance of the npn-type BJT in the common thyristor protection circuit is high and at least 1 kΩ. A solid line 52 shows the I-V characteristic obtained if the base resistance is low and several Ω to several tens of kΩ. A voltage level 53 shows a standby voltage equal to, for example, the power supply voltage Vdd. With the characteristic shown in FIG. 10, the hold voltage obtained if the base resistance of the npn-type BJT is high has a voltage value smaller than the value for the standby voltage level 53 as shown by the solid circle 54. However, the hold voltage obtained if the base resistance of the npn-type BJT is low has a voltage value larger than the value for the standby voltage as shown by a solid circle 55. Consequently, the hold voltage can also be increased above the standby voltage by reducing the resistance value of the base resistance of the npn-type BJT constituting the thyristor.

As described above, according to the configuration in which the diode is connected in series with the thyristor in order to prevent latch-up that may occur in the electrostatic protection circuit, the series insertion of the diode may degrade the discharge capability owing to the parasitic resistance of the diode and the forward voltage of the forward-biased diode.

Further, in order to prevent latch-up that may occur in the electrostatic protection circuit, the base resistance may be designed to have a small value to suppress the holding of carriers in the well region of the thyristor. This actually increases the turn-on time of the thyristor.

### SUMMARY OF THE INVENTION

An electrostatic protection circuit according to a basic configuration includes a thyristor that discharges an excess charge generated between a first power supply terminal and a second power supply terminal having a lower voltage than the first power supply terminal, a trigger device that supplies a current turning on the thyristor, and an electrostatic discharge element placed between the first power supply terminal and the second power supply terminal in parallel with thyristor and having a higher current supply capability than the trigger device at the same inter-power-terminal voltage, the electrostatic element changing to an on state in a time shorter than a turn-on time of the thyristor connected to the trigger device and at a voltage lower than a turn-on voltage of the thyristor.

### BRIEF DESCRIPTION OF THE DRAWINGS

FIG. 1 is a circuit diagram showing the configuration of an electrostatic protection circuit according to a first embodiment;

FIG. 2 is a characteristic diagram showing the current-voltage characteristic of the electrostatic protection circuit according to the first embodiment in comparison with a first conventional example;

FIG. 3 is a circuit diagram showing the configuration of an electrostatic protection circuit according to a second embodiment;

FIG. 4 is a circuit diagram showing the configuration of an electrostatic protection circuit according to a third embodiment;

FIG. 5 is a circuit diagram showing the configuration of an electrostatic protection circuit according to a fourth embodiment;

FIG. 6 is a circuit diagram showing the configuration of an electrostatic protection circuit according to a fifth embodiment;

FIG. 7 is a circuit diagram showing the configuration of an electrostatic protection circuit according to a sixth embodiment;

FIG. 8 is a circuit diagram showing the configuration of an electrostatic protection circuit according to a seventh embodiment;

FIG. 9 is a characteristic diagram illustrating the current-voltage characteristics of a common thyristor protection circuit and a first conventional example; and

FIG. 10 is a characteristic diagram illustrating a variation in current-voltage characteristic depending on the base resistance value of an npn-type BJT in the common thyristor protection circuit and a second conventional example.

### DETAILED DESCRIPTION OF THE INVENTION

With reference to the accompanying drawings, a detailed description will be given of embodiments of an electrostatic protection circuit according to the present invention.

### First Embodiment

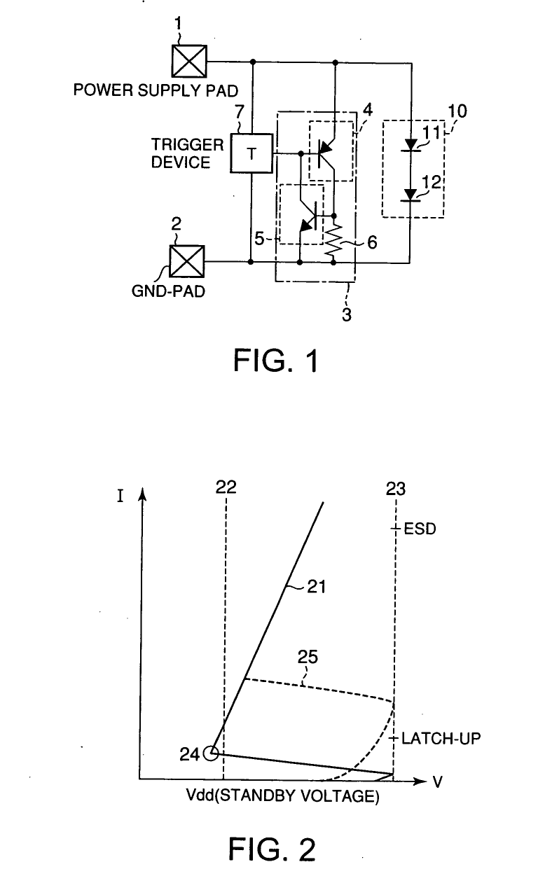

FIG. 1 is a circuit diagram showing the configuration of an electrostatic protection circuit according to a first embodiment of the present invention. In the figure, the electrostatic protection circuit has a thyristor 3 provided between a power supply pad 1 and a ground pad 2. The thyristor 3 includes a combination of a pnp-type BJT 4 and an npn-type BJT 5. The npn-type BJT 5 has a base resistor 6 between its base and emitter. The illustration of base resistor of the pnp-type BJT 4 is omitted. The resistor 6 offers a resistance between the base and emitter of the npn-type BJT 5, that is, a composite resistance of a p well and p substrate resistance and an additional resistance.

A trigger device 7 and an electrostatic discharge circuit 10 are provided between the power supply pad 1 and the ground pad 2; the trigger device 7 is connected in parallel with the thyristor 3 to supply a trigger signal to the base terminal of the pnp-type BJT 4 and the electrostatic discharge circuit 10 is connected in parallel with the thyristor 3 and trigger device 7. In the first embodiment, the electrostatic discharge circuit 10 includes a plurality of, at least two diodes 11 and 12 connected so as to pass a current forward between the power supply pad 1 and the ground pad 2. The added electrostatic protection circuit 10 is designed so that a possible leakage current does not pose any problem in a normal operation state. This should be noted particularly if a plurality of diodes are used.

The trigger device 7 generates a current required for the thyristor 3 to be turned on according to a difference in potential between the power supply pad 1 and the ground pad 2. Although not shown in the drawings, possible examples of the trigger device 7 include one or more diodes and a MOS transistor having a gate controlled by a time constant circuit.

The series-connected diodes 11 and 12 in the electrostatic discharge circuit 10 is designed so as to have a larger quantity of current than the trigger device 7 with respect to the same difference in potential between the power supply pad 1 and ground pad 2 connected in parallel. In an actual example, since an electrostatic protection circuit using a normal thyristor such as the one described in the common thyristor protection circuit has a turn-on current of at most about 10 milliamperes (mA), it is desirable to use a diode (P+/N well diode) constructed in an N well region of peripheral length 40 to 80 μm in order to raise the turn-on current to about 300 to 600 milliamperes (mA). The resistor connected between the base and emitter of the npn-type BJT 5 desirably has a resistance value of at least 1 kΩ.

With reference to the characteristic diagram in FIG. 2, description will be given of operations of the electrostatic protection circuit according to the first embodiment configured as described above. In the electrostatic protection circuit shown in FIG. 1, before the trigger device 7 has supplied a turn-on current to the N well region of the thyristor 3, a current starts to flow through the parallel-connected diodes 11 and 12 in the electrostatic discharge circuit 10. In FIG. 2, a solid waveform 21 shows the current-voltage characteristic of the electrostatic discharge circuit 10 in which the resistor 5 in the thyristor 3 has a large resistance value of at least 1 kΩ. A dashed line 22 shows the value of the voltage Vdd, serving as a standby voltage. A dashed line 23 shows the value of the turn-on voltage.

Without the electrostatic discharge element 10 according to the first embodiment, the hold voltage 24 is lower than the standby voltage 22 when the resistor 5 has a large resistance value of at least 1 kΩ. However, when the electrostatic discharge circuit 10 according to the first embodiment is provided in parallel, such a characteristic as the one shown by a dashed line 25 is observed within the range from a voltage value larger than that of the standby voltage 22 to the turn-on voltage 23. That is, the discharge capability of the whole electrostatic protection circuit 10 is determined depending on the discharge capability of the diodes 11 and 12 connected in parallel as shown by the dashed waveform 25, until the turn-on voltage 23 determined by the constitution of the trigger device 7 is reached. After the turn-on, the discharge capability is as shown by the solid waveform 21 as in the case of normal thyristors.

The electrostatic protection circuit shown in FIG. 1 and configured as described above is effective for preventing inadvertent turn-on caused by application of an overcurrent surge that is smaller than the electrostatic surge. This provides a margin for an increase in the turn-on current for the electrostatic protection circuit as a whole, which is ensured by the diodes 11 and 12 connected in parallel. Further, the turn-on current can be increased without the need to reduce the resistance value of the resistor 6 between the base and emitter of the npn-type BJT 5. This avoids adverse effects on the turn-on time of the thyristor. Furthermore, before the thyristor 3 is turned on, the parallel-connected diodes 11 and 12 of the electrostatic discharge element 10 partly discharge an electrostatic surge. The diodes require a shorter time to change to the on state than the thyristor. This prevents an overcurrent from being generated between the power supply pad 1 and the ground pad 2 by the electrostatic surge (overcurrent surge), which rises quickly; the overcurrent may destroy the internal circuit. The present embodiment simultaneously improves the latch-up resistance of the electrostatic protection circuit and the high-speed turn-on performance of the element while allowing the electrostatic protection circuit to maintain its discharge capability.

Further, provided that there is no capacitance (c) on the device side of the electrostatic discharge element 10 connected in parallel with the thyristor 3, the electrostatic discharge element may be used not only between Vdd and Vss, that is, between the power supplies, but also between an I/O terminal and the power supply terminal, that is, between the I/O terminal and the Vdd/Vss terminal, to protect I/Os.

### Second Embodiment

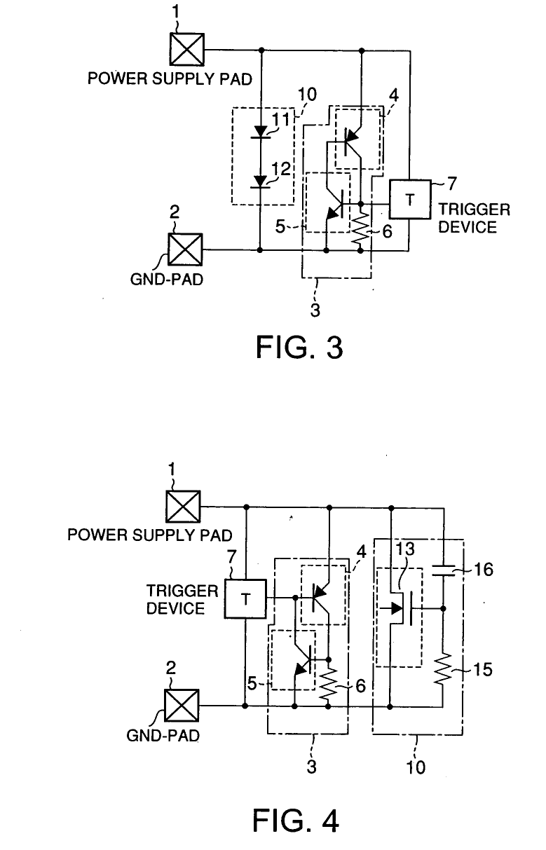

Now, with reference to FIG. 3, description will be given of an electrostatic protection circuit according to a second embodiment of the present invention. Some components in FIG. 3 are the same as or correspond to those in FIG. 1 which have the same reference numerals. The circuit in FIG. 3 has a configuration similar to that in the first embodiment except that the trigger device 7 is connected to the base terminal of the npn-type BJT 5 and that parts of the electrostatic discharge element 10 which are connected in parallel with the power supply pad 1 and ground pad 2 are closer to the pads than the thyristor 3. Accordingly, in the electrostatic protection circuit according to the second embodiment, the parallel positions of the trigger device 7 to which the power supply pad 1 and the ground pad 2 are connected farther from the pads than those of the thyristor 3. On the basis of this configuration, the second embodiment performs the same operations and produces the same effects as those of the first embodiment.

That is, also in the electrostatic protection circuit according to the second embodiment, the electrostatic discharge element 10 includes the at least two diodes 11 and 12. The peripheral length and number of diodes 11 and 12 are designed so that the diodes have a higher current supply capability than the trigger circuit 7 at the same voltage between the power supply terminals 1 and 2.

Further, provided that there is no capacitance (c) on the device side of the electrostatic discharge element 10 connected in parallel with the thyristor 3, the electrostatic discharge element may be used not only between Vdd and Vss, that is, between the power supplies, but also between an I/O terminal and the power supply terminal, that is, between the I/O terminal and the Vdd/Vss terminal, to protect I/Os.

### Third Embodiment

In the description of the electrostatic protection circuit according to the first and second embodiments described above, the electrostatic discharge element 10 includes a plurality of diodes cascaded in multiple stages having at least two stages. However, the present embodiment is not limited to this. The electrostatic discharge element 10 may include other devices.

For example, in an electrostatic protection circuit according to a third embodiment of the present invention shown in FIG. 4, the electrostatic discharge element includes a field effect transistor. The third embodiment will be described in detail. The electrostatic protection circuit according to the third embodiment shown in FIG. 4 is the same as that described in the first embodiment except that the electrostatic discharge element 10, connected in parallel with the thyristor 3, includes an nMOS (Metal Oxide Semiconductor) transistor 13, a resistance element 15 for gate control, and a capacitive element 16. The nMOS transistor 13 includes a thick film having a high threshold voltage Vth. The threshold voltage Vth and a gate width W determine turn-on current for the electrostatic protection circuit.

As described above, in the electrostatic protection circuit according to the third embodiment, the electrostatic discharge element 10 includes the n-channel MOS transistor 13. A gate of the n-channel MOS transistor 13 is connected to the junction point between first terminals of the resistance element 15 and capacitive element 16 connected in series. A second terminal of the resistance element 15 is connected to the second power supply terminal 2. A second terminal of the capacitive element 16 is connected to the first power supply terminal 1. The resistance element 15 and capacitive element 16 connected in series are connected in parallel with the n-channel MOS transistor 13. The gate width of the n-channel MOS transistor 13 is designed so that when turned on, the n-channel MOS transistor 13 has a higher current supply capability than the trigger circuit 7 at the same voltage between the power terminals 1 and 2.

In the electrostatic protection circuit according to the third embodiment configured as described above, the supply of a positive surge current raises the gate potential of the nMOS transistor 13 to the vicinity of the power supply voltage Vdd of the power supply pad 1. This turns on the nMOS transistor 13. Before the voltage between the power pad 1 and the ground pad 2 rises to the turn-on voltage determined by the configuration of the trigger circuit 7, the discharge capability of the electrostatic protection circuit as a whole is determined depending on the discharge capability of the nMOS transistor 13 connected in parallel. The other operations are the same as those of the diodes described for the electrostatic protection circuit according to the first embodiment.

The electrostatic protection circuit according to the third embodiment configured as described above can not only produce the effects described in the first embodiment but also reduce the quantity of leakage current during normal operations to the off leakage level of the nMOS transistor 13 when the leak current of the trigger circuit 7 can be negligible.

### Fourth Embodiment

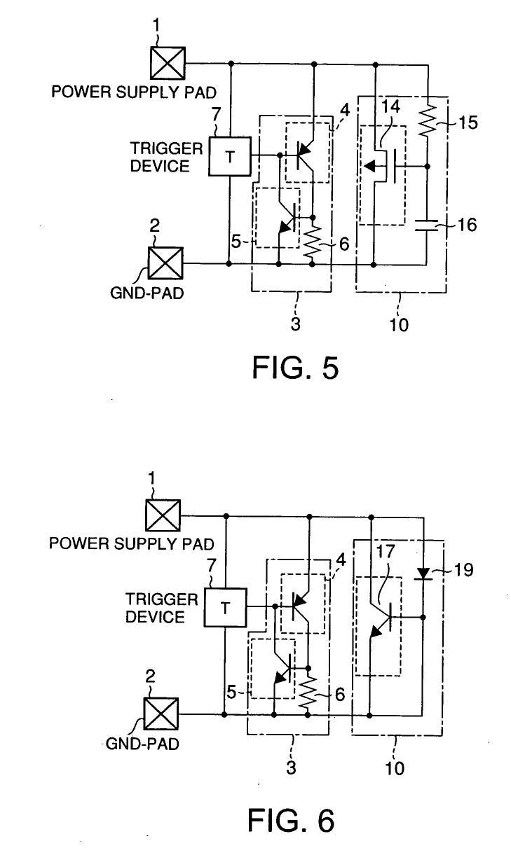

FIG. 5 shows an electrostatic protection circuit according to a fourth embodiment of the present invention. The configuration of the fourth embodiment is the same as that of the electrostatic protection circuit according to the third embodiment except that the electrostatic discharge element 10, connected in parallel with the thyristor 3, includes a pMOS transistor 14 and that the cascade connection between the resistance element 15 and capacitive element 16 is reverse to that in the third embodiment, the cascade connection being used for controlling the gate electrode of the MOS transistor 14.

In the electrostatic protection circuit according to the fourth embodiment, the electrostatic discharge element 10 includes the p-channel MOS transistor 14. A gate of the p-channel MOS transistor 14 is connected to the junction point between the first terminals of the resistance element 15 and capacitive element 16 connected in series. The second terminal of the resistance element 15 is connected to the first power supply terminal 1. The second terminal of the capacitive element 16 is connected to the second power supply terminal 2. The resistance element 15 and capacitive element 16 connected in series are connected in parallel with the p-channel MOS transistor 14. The gate width of the p-channel MOS transistor 14 is designed so that when turned on, the p-channel MOS transistor 14 has a higher current supply capability than the trigger circuit 7 at the same voltage between the power terminals 1 and 2.

The effects of the electrostatic protection circuit according to the fourth embodiment configured as described above are similar to those of the electrostatic protection circuit according to the third embodiment. Accordingly, duplicate descriptions are omitted.

### Fifth Embodiment

In the description of the electrostatic protection circuits according to the above third and fourth embodiments, the electrostatic discharge element 10 includes the n- or p-channel MOS transistor 13 or 14. However, the present embodiment is not limited to this. The electrostatic discharge element 10 may include a bipolar transistor (BJT)

FIG. 6 is a circuit diagram showing an electrostatic protection circuit according to the fifth embodiment in which the electrostatic discharge element 10 includes an npn-type BJT 17. In FIG. 6, the electrostatic discharge element 10 is connected between the power supply terminal 1 and the ground terminal 2 in parallel with the thyristor 3. The npn-type BJT 17 has a collector terminal connected to the power supply terminal 1 and an emitter terminal connected to the ground terminal 2. A diode 19 is connected between the collector terminal and a base terminal of the npn-type BJT 17 so as to pass a current forward from the collector to the base. The diode 19 thus supplies a current to the base terminal of the npn-type BJT 17.

In the electrostatic protection circuit according to the fifth embodiment, the electro static discharge element 10 includes the npn-type BJT 17. The diode 19 is connected in parallel with the npn-type BJT 17 between the base of the npn-type BJT 17 and the junction point between the power supply pad 1 and the collector of the npn-type BJT 17 so as to pass a current from the collector to the base. An anode of the diode 19 is connected to the junction between the power supply terminal 1 and the collector terminal of the npn-type BJT 17. A cathode of the diode 19 is connected to the base of the npn-type BJT 17. The npn-type BJT 17 is designed so that when turned on, the npn-type BJT 17 has a higher current supply capability than the trigger circuit 7 at the same inter-power-terminal voltage.

In the electrostatic protection circuit according to the fifth embodiment configured as described above, a current is drawn to the BJT 17 before the thyristor 3 is turned on, by adjusting the size and number of diodes 19 connected to the base terminal of the npn-type BJT 17, constituting the electrostatic discharge element 10, as well as the size of the BJT 17, the diodes 19 supplying a current. Although FIG. 6 shows only one diode 19, it is possible to provide the most desirable number of diodes 19 according to the power supply voltage required for normal operations while avoiding an increase in the quantity of leakage current; it is further possible to provide the most desirable number of diodes 19 so as to allow the diodes 19 to be turned on more quickly than the thyristor 3.

Further, provided that there is no capacitance (c) on the device side of the electrostatic discharge element 10 connected in parallel with the thyristor 3, the electrostatic discharge element may be used not only between Vdd and Vss, that is, between the power supplies, but also between an I/O terminal and the power supply terminal, that is, between the I/O terminal and the Vdd/Vss terminal, to protect I/Os.

### Sixth Embodiment

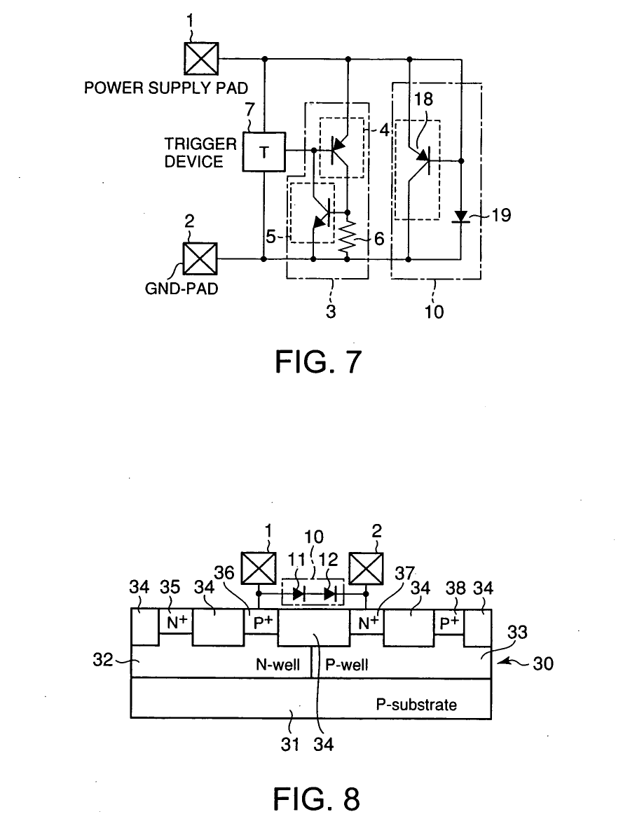

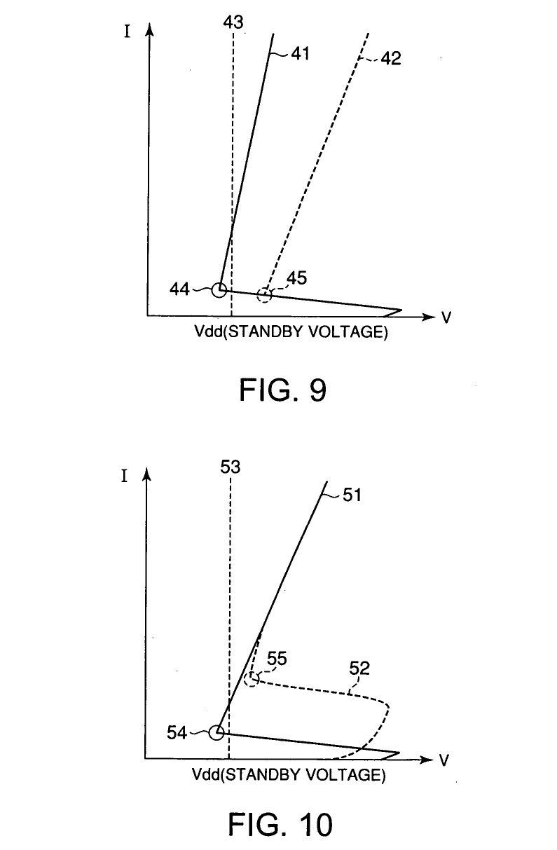

In the electrostatic protection circuit according to the fifth embodiment described above, the electrostatic discharge element 10 includes an npn-type BJT 17. The present embodiment is not limited to this. The electrostatic discharge element 10 may include a pnp-type bipolar transistor (BJT). In the electrostatic protection circuit according to the sixth embodiment shown in FIG. 7, the electrostatic discharge element 10 includes a pnp-type BJT 18. A diode 19 is connected in parallel between a base of the pnp-type BJT 18 and the junction point between a collector of the pnp-type BJT 18 and the ground terminal 2 so as to pass current forward from the base to the junction point. An anode of the diode 19 is connected to the base of the pnp-type BJT 18. A cathode of the diode 19 is connected to the junction point between the ground terminal 2 and the collector of the transistor 18. The pnp-type BJT 18 is designed so that when turned on, the pnp-type BJT 18 has a higher current supply capability than the trigger circuit 7 at the same inter-power-terminal voltage.

In the specific example described for the electrostatic protection circuits according to the fifth and sixth embodiments, the npn-type or pnp-type BJT 17 or 18 is formed as a component of the electrostatic discharge element 10. The BJTs in these embodiments may each be a parasitic BJT formed under the gate of a MOS.

Further, provided that there is no capacitance (c) on the device side of the electrostatic discharge element 10 connected in parallel with the thyristor 3, the electrostatic discharge element may be used not only between Vdd and Vss, that is, between the power supplies, but also between an I/O terminal and the power supply terminal, that is, between the I/O terminal and the Vdd/Vss terminal, to protect I/Os.

### Seventh Embodiment

For any of the electrostatic protection circuits according to the first to sixth embodiments, with reference to the circuit diagram, description is given of the trigger circuit 7 and electrostatic discharge element 10 connected in parallel with the thyristor 3 connected between the power supply terminal 1 and the ground terminal 2. Now, an electrostatic protection circuit according to the seventh embodiment will be described with reference to the sectional view of a semiconductor device shown in FIG. 8.

FIG. 8 shows the structure of a thyristor protection element 30 constructed on a semiconductor substrate such as silicon. In FIG. 8, the thyristor protection element 30 includes a P-type semiconductor substrate 31, and an N well region 32 and a P well region 33 selectively formed on the substrate 31. The N well region 32 is used as the base of the pnp-type BJT 4 and as the collector of the npn-type BJT 5, the pnp- and npn-type BJTs 4 and 5 being shown in FIGS. 1 and 3 to 7. The P well region 33 is similarly used as the base of the npn-type BJT 5 and as the collector of the pnp-type BJT 4.

A plurality of element isolation regions 34 are used to form a plurality of element regions 35 to 38 on each of the N well region 32 and the P well region 33. Specifically, the element regions include an N well contact 35 used as the gate G2 trigger terminal of the thyristor 3, an anode region 36 used as the emitter of the pnp-type BJT 4, a cathode region 37 used as the emitter of the npn-type BJT 5, and a P well contact 38 used as the gate G1 trigger terminal of the thyristor 3.

In this manner, the thyristor 3 and the trigger circuit 7 are formed on the substrate, with the power supply terminal 1 and the ground terminal 2 connected together by wiring. The electrostatic discharge element 10 according to the seventh embodiment is connected in parallel between the wires to the power supply terminal 1 and the ground terminal 2. Specifically, the series-connected diodes 11 and 12 are connected in parallel between the wires of both power supplies 1 and 2.

The electrostatic protection circuit according to the seventh embodiment shown in FIG. 8 has the same configuration as the latter example of improvement in the description of the first conventional example except for the electrostatic discharge element 10 connected in parallel between the power supply terminal 1 and the ground terminal 2, which is characteristic of the seventh embodiment. In the example of the improved electrostatic protection circuit according to the second conventional example, the base resistance is designed to have a small value so as to provide a structure in which carriers are unlikely to be held in the P well region 33 of the thyristor formed on the silicon. This increases the quantity of current required to turn on the thyristor to prevent inadvertent turn-on caused by power supply noise or the like.

However, the example of the improved electrostatic protection circuit according to the second conventional example has not been able to achieve both improvement of the latch-up resistance and appropriate control of the turn-on time. In the electrostatic protection circuit according to the seventh embodiment of the present invention, the electrostatic discharge element 10 is provided between the wires to the power supply terminal 1 and ground terminal 2 in parallel with the thyristor.

The above configuration increases the turn-on current for the thyristor, which is otherwise small, for the electrostatic protection circuit as a whole. This suppresses an electrostatic protection operation performed if an overcurrent such as power supply noise is supplied which is smaller than an electrostatic surge. Consequently, the latch-up resistance of the whole current is improved. It is also possible to ensure high-speed responsiveness to a rapid rising surge, which presents a problem for the thyristor, that is, quick turn-on performance while maintaining the discharge capacity.

What is claimed is:

1. An electrostatic protection circuit comprising:
a thyristor that discharges an excess charge generated between a first power supply terminal and a second power supply terminal having a lower voltage than the first power supply terminal;
a trigger device that supplies a current turning on the thyristor; and
an electrostatic discharge element placed between the first power supply terminal and the second power supply terminal in parallel with thyristor and having a higher current supply capability than the trigger device at the same inter-power-terminal voltage, the electrostatic element changing to an on state in a time shorter than a turn-on time of the thyristor connected to the trigger device and at a voltage lower than a turn-on voltage of the thyristor.

2. The electrostatic protection circuit according to claim 1, wherein the electrostatic discharge element has at least two, multiple diodes, and the peripheral length and number of multiple diodes are sufficient to provide a higher current supply capability than the trigger circuit at the same inter-power-terminal voltage.

3. The electrostatic protection circuit according to claim 2, wherein the multiple diodes are designed so as to provide a larger quantity of current than the trigger circuit with respect to the same difference in potential between the first power supply terminal and the second power supply terminal.

4. The electrostatic protection circuit according to claim 2, wherein the thyristor is provided between the first power supply terminal and the second power supply terminal, the trigger circuit is connected in parallel with the thyristor and between the thyristor and both first and second power supply terminals, and the electrostatic discharge element is connected in parallel with the thyristor and at a position farther from the first and second power supply terminals than a position where the trigger circuit is connected in parallel with the thyristor so that the electrostatic discharge element passes a current forward from the first power supply terminal to the second power supply terminal.

5. The electrostatic protection circuit according to claim 2, wherein the thyristor is provided between the first power supply terminal and the second power supply terminal, the electrostatic discharge element is connected in parallel with the thyristor so as to passes a current forward from the thyristor and the first power supply terminal to the second power supply terminal, and the trigger circuit is connected in parallel with the thyristor and at a position farther from the first and second power supply terminals than a position where the electrostatic discharge element is connected in parallel with the thyristor.

6. The electrostatic protection circuit according to claim 1, wherein the electrostatic discharge element has an n-channel MOS transistor having a gate connected to a junction point between first terminals of a capacitive element and a resistance element which are connected in series, a second terminal of the capacitive element is connected to the first power supply terminal, whereas a second terminal of the resistance element is connected to the second power supply terminal, so that the capacitive element and the resistance element which are connected in series are connected in parallel with the n-channel MOS transistor, and a gate width of the n-channel MOS transistor is configured so that when turned on, the n-channel MOS transistor has a higher current supply capability than the trigger circuit at the same inter-power-terminal voltage.

7. The electrostatic protection circuit according to claim 6, wherein n-channel MOS transistor has a thick film and has a high threshold voltage, and a turn-on current for the electrostatic protection circuit is determined by the threshold voltage and the gate width.

8. The electrostatic protection circuit according to claim 6, wherein the thyristor is provided between the first power supply terminal and the second power supply terminal, the trigger circuit is connected in parallel with the thyristor and between the thyristor and both first and second power supply terminals, and the n-channel MOS transistor is connected in parallel with the thyristor and at a position farther from the first and second power supply terminals than a position where the trigger circuit is connected in parallel with the thyristor.

9. The electrostatic protection circuit according to claim 1, wherein the electrostatic discharge element includes a p-channel MOS transistor having a gate connected to a junction point between first terminals of a capacitive element and a resistance element which are connected in series, and a second terminal of the capacitive element is connected to the first power supply terminal, whereas a second terminal of the resistance element is connected to the second power supply terminal, so that the capacitive element and the resistance element which are connected in series are connected in parallel with the p-channel MOS transistor.

10. The electrostatic protection circuit according to claim 9, wherein a gate width of the p-channel MOS transistor is configured so that when turned on, the p-channel MOS transistor has a higher current supply capability than the trigger circuit at the same inter-power-terminal voltage.

11. The electrostatic protection circuit according to claim 9, wherein the thyristor is provided between the first power supply terminal and the second power supply terminal, the trigger circuit is connected in parallel with the thyristor and between the thyristor and both first and second power supply terminals, and the p-channel MOS transistor is connected in parallel with the thyristor and at a position farther from the first and second power supply terminals than a position where the trigger circuit is connected in parallel with the thyristor.

12. The electrostatic protection circuit according to claim 1, wherein the electrostatic discharge element has an npn-type bipolar transistor, and a diode is connected in parallel between a base of the npn-type bipolar transistor and a junction between the first power supply terminal and a collector of the npn-type bipolar transistor so that the diode passes a current forward from the junction to the base, and wherein an anode of the diode is connected to the first power supply terminal, whereas a cathode of the diode is connected to the base of the npn-type bipolar transistor, and the npn-type bipolar transistor is configured so that when turned on, the npn-type bipolar transistor has a higher current supply capability than the trigger circuit at the same inter-power-terminal voltage.

13. The electrostatic protection circuit according to claim 12, wherein the multiple diodes are provided between the base of the npn-type bipolar transistor and the junction between the first power supply terminal and the collector of the npn-type bipolar transistor so that a most desirable number of diodes are connected.

14. The electrostatic protection circuit according to claim 12, wherein the thyristor is provided between the first power supply terminal and the second power supply terminal, the trigger circuit is connected in parallel with the thyristor and between the thyristor and both first and second power supply terminals, and the npn-type MOS transistor is connected in parallel with the thyristor and at a position farther from the first and second power supply terminals than a position where the trigger circuit is connected in parallel with the thyristor.

15. The electrostatic protection circuit according to claim 12, wherein the npn-type bipolar transistor is a parasitic BJT formed under a gate of a MOS.

16. The electrostatic protection circuit according to claim 1, wherein the electrostatic discharge element has a pnp-type bipolar transistor, and a diode is connected in parallel between a base of the pnp-type bipolar transistor and a junction between a collector of the pnp-type bipolar transistor and the second power supply terminal so that the diode passes a current forward from the base to the junction, and wherein an anode of the diode is connected to the base of the pnp-type bipolar transistor, whereas a cathode of the diode is connected to the junction between the second power supply terminal and the collector of the pnp-type bipolar transistor, and the pnp-type bipolar transistor is configured so that when turned on, the pnp-type bipolar transistor has a higher current supply capability than the trigger circuit at the same inter-power-terminal voltage.

17. The electrostatic protection circuit according to claim 16, wherein the multiple diodes are provided between the base of the pnp-type bipolar transistor and the junction between the collector of the pnp-type bipolar transistor and the second power supply terminal and so that a most desirable number of diodes are connected.

18. The electrostatic protection circuit according to claim 16, wherein the thyristor is provided between the first power supply terminal and the second power supply terminal, the trigger circuit is connected in parallel with the thyristor and between the thyristor and both first and second power supply terminals, and the pnp-type bipolar transistor is connected in parallel with the thyristor and at a position farther from the first and second power supply terminals than a position where the trigger circuit is connected in parallel with the thyristor.

19. The electrostatic protection circuit according to claim 16, wherein the pnp-type bipolar transistor is a parasitic BJT formed under a gate of a MOS.

20. The electrostatic protection circuit according to claim 1, wherein the electrostatic protection circuit is a thyristor protection element constructed on a semiconductor substrate, the thyristor protection element includes a P-type semiconductor substrate, and an N well region and P well region selectively formed on the semiconductor substrate, and the N well region is used as a base of a pnp-type BJT and as a collector of an npn-type BJT, whereas the P well region is used as a base of the npn-type BJT and as a collector of the pnp-type BJT, and wherein a plurality of isolation regions are used to form a plurality of element regions on each of the N well region and the P well region, and the circuit includes an N well contact used as a first gate trigger terminal of the thyristor, an anode region used as an emitter of the pnp-type BJT, a cathode region used as an emitter of the npn-type BJT, and a P well contact used as a second gate trigger terminal of the thyristor.
